(19) United States
(12) Patent Application Publication
(10) Pub. No.: US 2009/0068838 A1
(43) Pub. Date: Mar. 12, 2009

(54) METHOD FOR FORMING MICROPATTERNS IN SEMICONDUCTOR DEVICE

(75) Inventors: Won-Kyu KIM, Ichon-shi (KR); Ki-Lyoung Lee, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 12/164,009

(22) Filed: Jun. 28, 2008

(30) Foreign Application Priority Data
Sep. 12, 2007 (KR) 10-2007-0092642

(51) Int. Cl. H01L 21/306

(52) U.S. Cl. 438/692; 438/697; 257/E21.215; 257/E21.23

(57) ABSTRACT

A method for forming micropatterns in a semiconductor device includes forming a first etch stop layer over a etch target layer, forming a second etch stop layer over the first etch stop layer, forming a first sacrificial layer over the second etch stop layer, etching portions of the first sacrificial layer and second etch stop layer to form first sacrificial patterns, forming an insulation layer along an upper surface of the first etch stop layer, forming a second sacrificial layer over the insulation layer to cover the insulation layer, planarizing the second sacrificial layer and the insulation layer to expose the first sacrificial patterns, removing the first sacrificial patterns and the second sacrificial layer, etching the second etch stop layer and insulation layer to thereby form second sacrificial patterns, etching the first etch stop layer, and etching the etch target layer.

### CROSS-REFERENCE TO RELATED APPLICATIONS

The present invention claims priority of Korean patent application number 2007-0092642, filed on Sep. 12, 2007, which is incorporated by reference in its entirety.

### BACKGROUND OF THE INVENTION

The present invention relates to a method for fabricating micropatterns in a semiconductor device.

Recently, as semiconductors become highly integrated, a line and space (LS) under 40 nm is needed. However, typical exposure equipment cannot form a LS under 60 nm. Accordingly, a double patterning technology (DPT) has been introduced to embody a micro LS under 60 nm using the typical exposure equipment.

FIGS. 1A to 1D illustrate cross-sectional views describing a method for forming typical micropatterns through a DPT process. Referring to FIG. 1A, an etch target layer 101 is formed over a substrate 100. First and second hard masks 102, 103 are sequentially formed over a resultant structure.

A photoresist layer (not shown) is formed over the second hard mask 103. A mask process including photo-exposure and development is performed thereon using a photo mask to form first photoresist patterns 104.

Referring to FIG. 1B, an etch process is performed on the second hard mask 103 using the first photoresist patterns 104 as a mask. Thus, second hard mask patterns 103A are formed.

A photoresist layer (not shown) is formed over the first hard mask 102 and the second hard mask patterns 103A. Referring to FIG. 1C, a mask process is performed to form second photoresist patterns 105 between the second hard mask patterns 103A.

Referring to FIG. 1D, the first hard mask 102 is etched using the second hard mask patterns 103A and second photoresist patterns 105 as an etch mask. Thus, first hard mask patterns 102A are formed.

The etch target layer 101 is etched using the hard mask patterns 102A as an etch mask. Thus, micropatterns (also called microlines) are formed.

As described, in the typical method, the linewidth uniformity of micropatterns is dependent on the overlay accuracy of the first and second masks. To secure the linewidth uniformity of the micropatterns, the first and second masks are aligned to have a linewidth under 4 nm based on ‘I Mean I+3σ’. Since the typical photo-exposure equipment controls the 3σ to be under 7 nm, new equipment may need to be developed. However, it is difficult to embody this new equipment because of a technical limitation. Furthermore, as shown in FIG. 1C, a mask process is performed on a resultant structure including the second hard mask patterns 103A when forming the second photoresist patterns 105. Thus, the second hard mask patterns 103A may be damaged during this process to thereby change a critical dimension of the second hard mask patterns 103A.

### SUMMARY OF THE INVENTION

Embodiments of the present invention relate to a method for forming micropatterns in a semiconductor device.

In accordance with an aspect of the present invention, there is provided a method for forming micropatterns in a semiconductor device. The method includes providing an etch target layer, forming a first etch stop layer over the etch target layer, forming a second etch stop layer over the first etch stop layer, forming a first sacrificial layer over the second etch stop layer, etching portions of the first sacrificial layer and second etch stop layer to form first sacrificial patterns, forming an insulation layer along an upper surface of the first etch stop layer including the first sacrificial patterns, forming a second sacrificial layer over the insulation layer to cover the insulation layer, planarizing the second sacrificial layer and the insulation layer to expose the first sacrificial patterns, removing the first sacrificial patterns and the second sacrificial layer, etching the second etch stop layer and insulation layer to thereby form second sacrificial patterns, etching the first etch stop layer using the second sacrificial patterns as an etch barrier layer, and etching the etch target layer using the first etch stop layer as an etch barrier layer.

### BRIEF DESCRIPTION OF THE DRAWINGS

FIGS. 1A to 1D illustrate cross-sectional views of a typical method for forming micropatterns through a DPT process.

FIGS. 2A to 2J illustrate cross-sectional views of a method for forming micropatterns in a semiconductor device in accordance with an embodiment of the present invention.

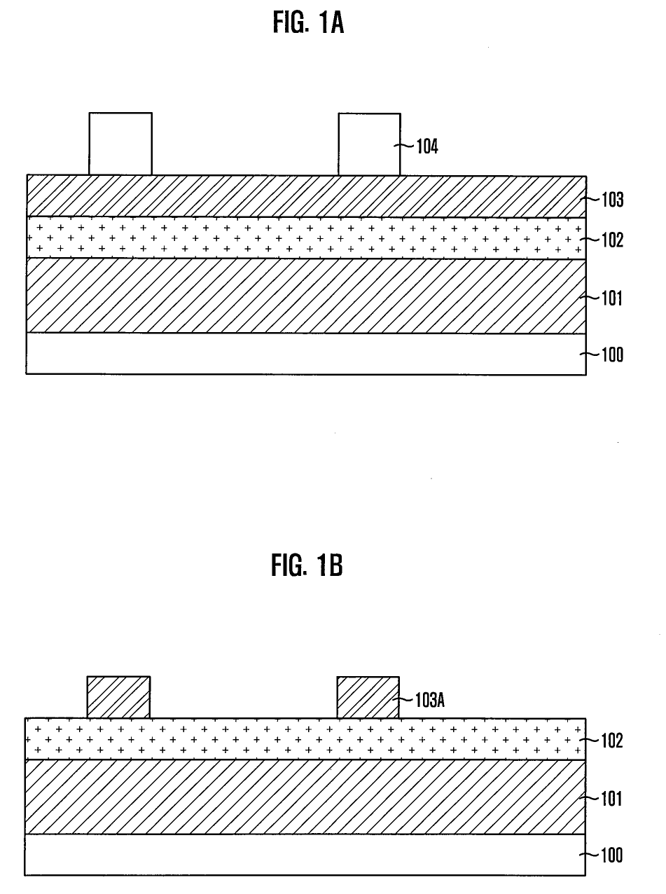

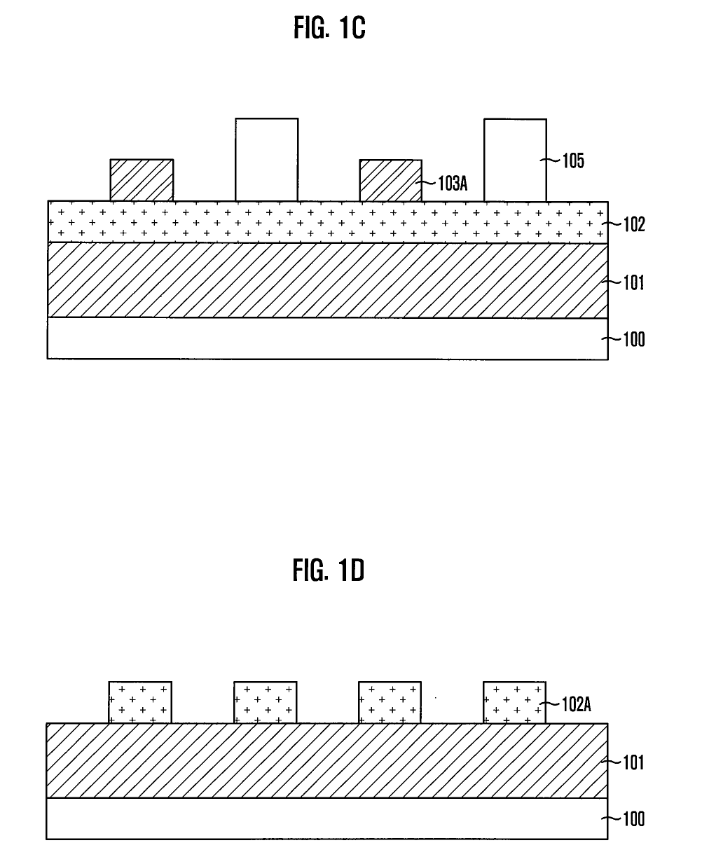

### DESCRIPTION OF SPECIFIC EMBODIMENTS

Embodiments of the present invention relate to a method for forming micropatterns in a semiconductor device.

The embodiments will be described with reference to the accompanying drawings. In the drawings, the illustrated thickness of layers and regions are exaggerated to facilitate explanation. When a first layer is referred to as being “on” a second layer or “on” a substrate, it could mean that the first layer is formed directly on the second layer or the substrate, or it could also mean that a third layer may exist between the first layer and the substrate. Furthermore, the same or like reference numerals throughout the various embodiments of the present invention represent the same or like elements in different drawings.

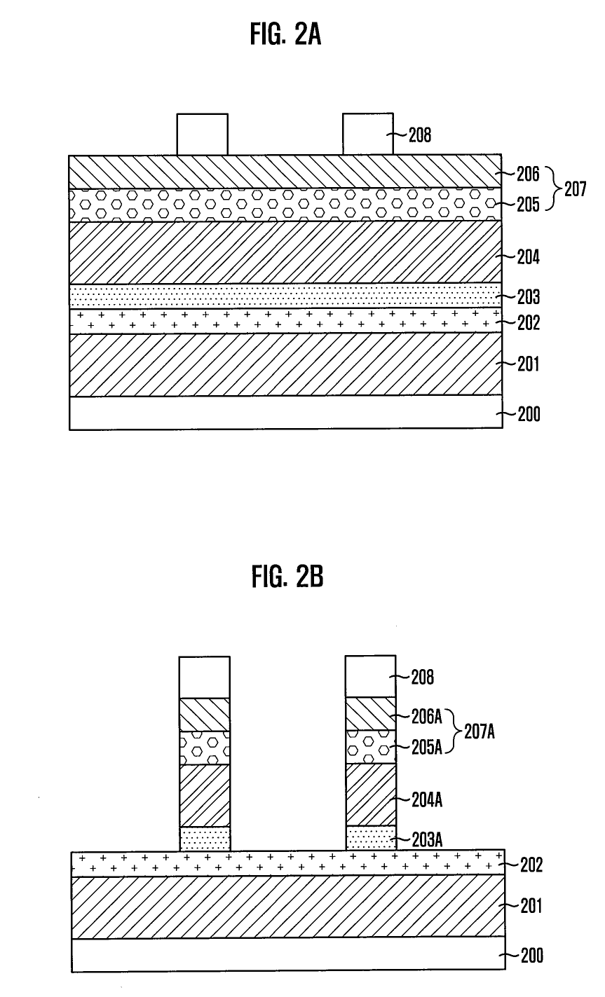

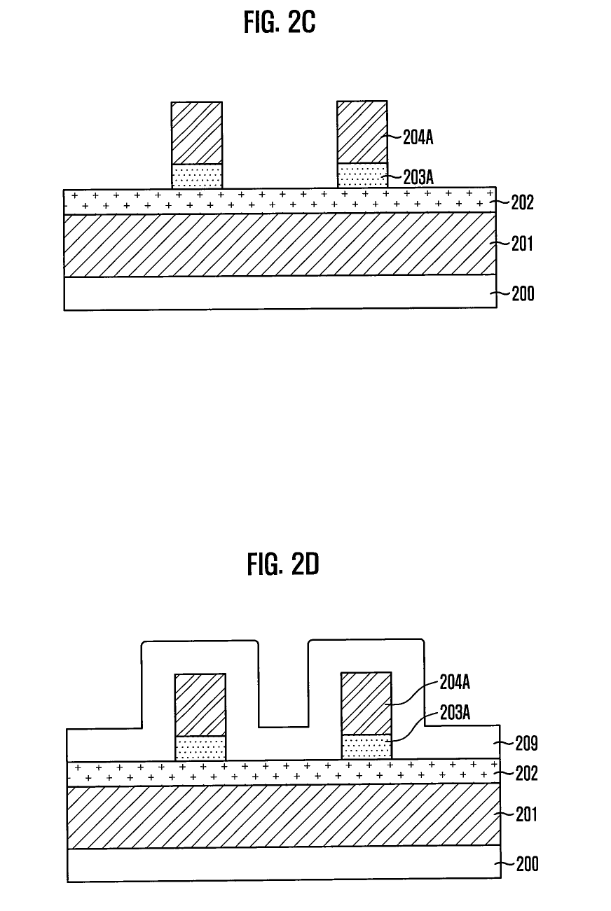

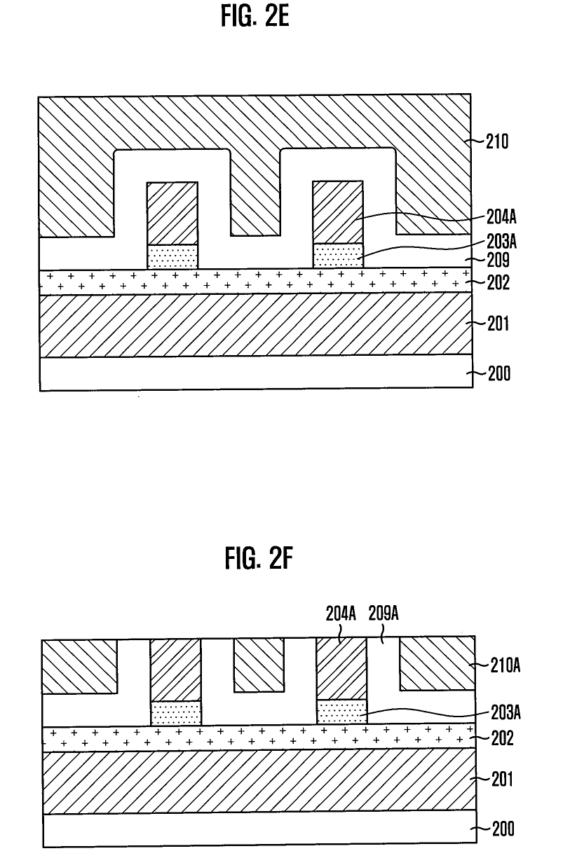

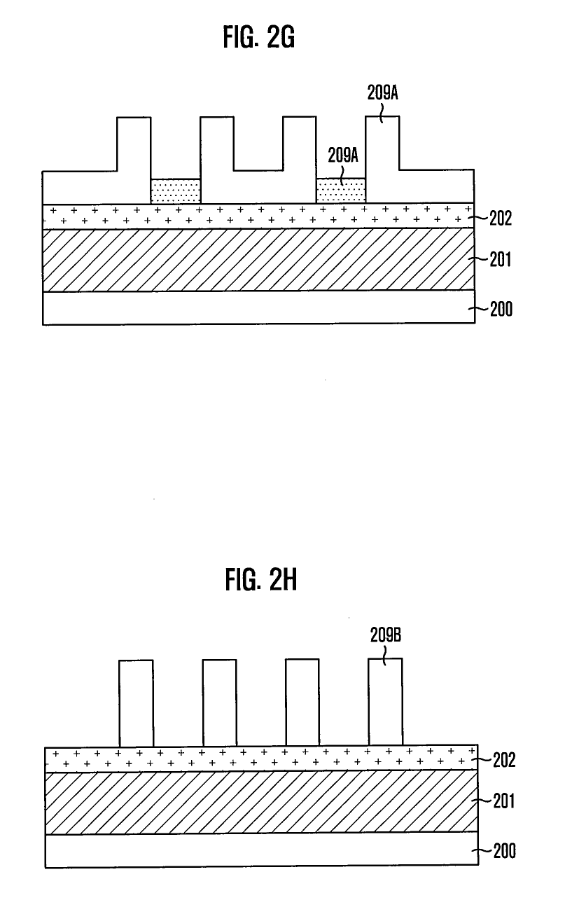

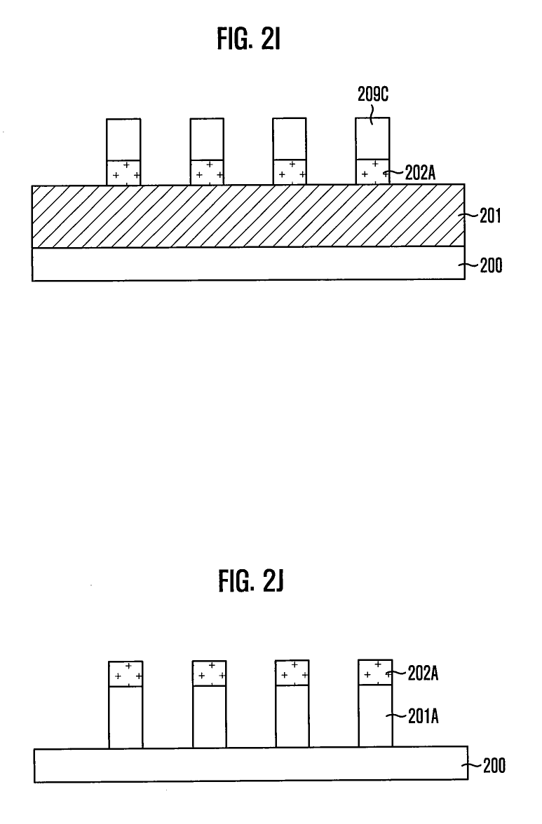

FIGS. 2A to 2J illustrate cross-sectional views of a method for forming micropatterns in a semiconductor device in accordance with an embodiment of the present invention. In this embodiment, a hard mask formed over a gate electrode is used as an etch target layer to form micropatterns in a semiconductor device.

Referring to FIG. 2A, a hard mask 201 functioning as an etch target layer is formed over a substrate 200. The hard mask 201 may include one selected from a group consisting of an oxide layer, a nitride layer, an oxy-nitride layer, a carbon containing layer (e.g., an amorphous carbon layer), a polycrystalline silicon layer, and a stack structure thereof. For instance, the oxide layer may be a silicon oxide (SiO₂) layer, the nitride layer may be a silicon nitride (Si₃N₄) layer, and the oxy-nitride layer may be a silicon oxy-nitride (SiON) layer.

A first etch stop layer 202 is formed over the hard mask 201. The first etch stop layer 202 may include a material having an etch selectivity ratio with the hard mask 201. For instance, the first etch stop layer 202 may include one selected from a group consisting of an oxide layer (e.g., an SiO₂ layer), nitride layer (e.g., a Si₃N₄ layer), oxy-nitride layer (e.g., a SiON layer), and polycrystalline silicon layer (e.g., a doped or an un-doped polycrystalline silicon layer).

A second etch stop layer 203 is formed over the first etch stop layer 202. The second etch stop layer 203 may include a material having a high etch selectivity with the first etch stop layer 202. Particularly, the second etch stop layer 203 may include a material for a subsequent an insulation layer 209 for a spacer (refer to FIG. 2D). For instance, the second etch stop layer 203 may include one selected from a group consisting of an oxide layer (e.g., a SiO₂ layer), nitride layer (e.g., the Si₃N₄ layer), oxy-nitride layer (e.g., the SiON layer), and polycrystalline silicon layer (e.g., a doped or an un-doped polycrystalline silicon layer). The second etch stop layer 203 is formed to reduce pattern defects caused by a deformation of immersion photoresist patterns and a decrease in an etch selectivity ratio.

A first sacrificial layer 204 is formed over the second etch stop layer 203. The first etch stop layer 204 may include a material having a high etch selectivity ratio with the second etch stop layer 203. The first sacrificial layer 204 may include an oxide layer (e.g., a SiO₂ layer) or a spin coating layer which can be easily removed through a wet etch process. Also, the first sacrificial layer 204 may include a polysilicon layer or amorphous carbon layer which can be easily removed through the dry etch process. The oxide layer may include a tetra ethyle ortho silicate (TEOS) layer or a high aspect ratio process (HARP) layer. The spin coating layer may include a spin on dielectric (SOD) layer or a spin on glass (SOG) layer.

An anti-reflection layer 207 may be formed over the first sacrificial layer 204. Herein, the anti-reflection layer 207 may include a single layer of a bottom anti-reflective coating (BARC) layer or a stack structure of a dielectric anti-reflective coating (DARC) layer 205 and the BARC layer 206 formed through a chemical vapor deposition (CVD) process. For instance, the DARC layer 205 may include a material with a refractive index of 1.95 and an extinction coefficient of 0.53. The BARC layer 206 may include an organic material.

Photoresist patterns 208 are formed over the anti-reflection layer 207. Herein, a photo-exposure process forming the photoresist patterns 208 are performed to have an LS ratio of approximately 1:3 (L:S). This pattern and ratio is then transferred to a final etch stop layer. That is, in the final etch stop layer, the ratio of the line to the space is approximately 1:3. The photo-exposure process is performed while having a line to space ratio of approximately 1:2.5 to approximately 1:3.5.

Referring to FIG. 2B, the anti-reflection layer 207, first sacrificial layer 204, and second etch stop layer 203 are etched using the photoresist patterns 208 to create the anti-reflective patterns 207A, first sacrificial patterns 204A and second etch stop patterns 203A, respectively. Thus, the first etch stop layer 202 is exposed. A dry etch process or a wet etch process may be used.

Referring to FIG. 2C, the photoresist patterns 208 (refer to FIG. 2B) and anti-reflection patterns 207A (refer to FIG. 2B) are removed. The removal process may be an ashing process using an oxygen (O₂) plasma. Thus, first sacrificial patterns 204A are exposed.

Referring to FIG. 2D, the insulation layer 209 is formed over the first etch stop layer 202 including the first sacrificial patterns 204A. The insulation layer 209 is formed with a uniform thickness along a top, bottom, and sidewalls of the resultant structure including the first sacrificial patterns 204A. The insulation layer 209 includes a material with a fine characteristic, i.e., more than approximately a step coverage rate of 0.9. Here, the step coverage rate indicates how uniform (in terms of thickness) a material is deposited. That is, the step coverage rate indicates a ratio of a first thickness T1 (e.g., thickness deposited on the first etch stop layer 202) to a second thickness T2 (e.g., thickness deposited on the sidewalls of the first sacrificial patterns 204A). Thus, a step coverage rate over approximately 0.9 indicates that a ratio of the second thickness T2 the first thickness T1 is approximately 0.9:1. Likewise, to acquire the step coverage over approximately 0.9, the insulation layer 209 may be formed through an atomic layer dielectric (ALD) process. Also, the insulation layer 209 may include a material used in the first etch stop layer 202 or a material having substantially the same similar etch rate with the first etch stop layer 202. Preferably, an etch ratio of the insulation layer 209 to the first etch stop layer 202 is approximately 1:1.

Referring to FIG. 2E, a second sacrificial layer 210 is formed to cover the insulation layer 209. At this time, the second sacrificial layer 210 may include a material used in the first sacrificial pattern 204A or a material having substantially the same etch rate with the first sacrificial pattern 204A. Preferably, an etch ratio of the insulation layer 209 to the first sacrificial pattern 204A is approximately 1:1. The second sacrificial layer 210 is formed to gap fill between the first sacrificial patterns 204A.

Referring to FIG. 2F, the second sacrificial layer 210 and the insulation layer 209 are planarized to expose an upper portion of the first sacrificial patterns 204A and creates the second sacrificial patterns 210A and insulation patterns 209A, respectively. The planarization process may be performed through an etch process using a plasma etch apparatus (e.g., an etch-back process) or a chemical mechanical polishing (CMP) process.

Referring to FIG. 2G, the first and second sacrificial patterns 204A, 210A (refer to FIG. 2F) are selectively removed using the second etch stop pattern 203A and insulation patterns 209A as an etch barrier layer. For instance, when the first and second sacrificial patterns 204A and 210A include the oxide layer, an etch process is performed using diluted hydrogen fluoride (DHF) or a buffered oxide etchant (BOE) solution. When the first and second sacrificial patterns 204A and 210A include the amorphous carbon layer, the dry etch process is performed using nitrogen (N₂) and O₂. When the first and second sacrificial patterns 204A and 210A include the polycrystalline silicon layer, the dry etch process is performed using one of a chlorine (Cl₂) gas, hydrogen bromide (HBr) gas, and a gas-mixture thereof.

Referring to FIG. 2H, the insulation patterns 209A and second etch stop patterns 203A are etched using the first etch stop layer 202 as an etch barrier layer to form second sacrificial patterns 209B. The etch process may be a dry etch process, e.g., an etch-back process. The etch process is performed with a high etch selectivity ratio condition to minimize damage of the first etch stop layer 202.

Referring to FIG. 2I, the first etch stop patterns 202A are etched using the third sacrificial patterns 209C as an etch barrier. The etch process may be a dry etch stop process.

Referring to FIG. 2J, the hard mask patterns 201A are etched using the third sacrificial patterns 209C (refer to FIG. 2I) and etch stop patterns 202A, particularly, the first etch stop pattern 202A, as an etch barrier layer. Thus, hard mask patterns with a micropattern is formed.

In this invention, micropatterns which are formed through just one mask process as opposed to the typical method. Furthermore, a critical dimension ununiformity of a linewidth caused by a misalignment during the two mask processes for a typical DPT process can be improved.

While the present invention has been described with respect to the specific embodiments, the above embodiments of the present invention are illustrative and not limitative. In this invention, the hard mask is used as an etch target layer. However, the etch target layer can be any other materials (e.g., a conductive layer) used for the semiconductor device. It will be apparent to those skilled in the art that various changes and modifications may be made without departing from the spirit and scope of the invention as defined in the following claims.

What is claimed is:

1. A method for forming micropatterns in a semiconductor device, the method comprising:
providing an etch target layer;
forming a first etch stop layer over the etch target layer;
forming a second etch stop layer over the first etch stop layer;
forming a first sacrificial layer over the second etch stop layer;
etching portions of the first sacrificial layer and the second etch stop layer to form first sacrificial patterns;
forming an insulation layer along an upper surface of the first etch stop layer including the first sacrificial patterns;
forming a second sacrificial layer over the insulation layer to cover the insulation layer;
planarizing the second sacrificial layer and the insulation layer to expose the first sacrificial patterns;
removing the first sacrificial patterns and the second sacrificial layer;
etching the second etch stop layer and the insulation layer to form second sacrificial patterns;
etching the first etch stop layer using the second sacrificial patterns as an etch barrier layer; and
etching the etch target layer using the first etch stop layer as an etch barrier layer.

2. The method of claim 1, wherein the first and second sacrificial layers include the same material.

3. The method of claim 1, wherein the first and second sacrificial layers include materials having substantially the same etch rate.

4. The method of claim 1, wherein the first and second sacrificial layers include a material having a high etch selectivity to the first and second etch stop layers.

5. The method of claim 1, wherein the first and second sacrificial layers include a material having a high etch selectivity to the insulation layer.

6. The method of claim 1, wherein the first and second sacrificial layers include one selected from a group consisting of an oxide layer, a spin coating layer, a polycrystalline silicon layer, and an amorphous carbon layer.

7. The method of claim 1, wherein the insulation layer includes a material used to form the second etch stop layer.

8. The method of claim 1, wherein the insulation layer includes a material having substantially the same etch rate with the second etch stop layer.

9. The method of claim 1, further comprising, forming an anti-reflection layer over the first sacrificial layer, after forming the first sacrificial layer.

10. The method of claim 9, wherein the anti-reflection layer includes a bottom anti-reflective coating (BARC) layer.

11. The method of claim 9, wherein the anti-reflection layer includes a stack structure of a dielectric anti-reflective coating (DARC) layer and the BARC layer.

12. The method of claim 1, wherein removing the first sacrificial patterns and the second sacrificial layer is performed through a dry or wet etch process.

13. The method of claim 1, wherein planarizing the second sacrificial layer and the insulation layer is performed through an etch-back process or a chemical mechanical polishing (CMP) process.
